(19) United States
(12) Patent Application Publication
(10) Pub. No.: US 2007/0210818 A1
(43) Pub. Date: Sep. 13, 2007

(54) Temperature monitoring and control apparatus and method

(75) Inventors: Martin P. Goetz, Cary, NC (US); Gary Ernest O'Neil, Raleigh, NC (US); Bradford L. Thomasson, South Boston, VA (US)

Correspondence Address: IBM CORPORATION, PO BOX 12195, DEPT YXSA, BLDG 002, RESEARCH TRIANGLE PARK, NC, 27709, US

(73) Assignee: INTERNATIONAL BUSINESS MACHINES CORPORATION, ARMONK, NY (US)

(21) Appl. No.: 11/371,382

(22) Filed: Mar. 9, 2006

(51) Int. Cl. G01R 31/02

(52) U.S. Cl. 324/760

(57) ABSTRACT

Apparatus and methods for monitoring temperature which employ certain characteristics of diodes in an effective way to monitor the temperature of a heat generating device and enable use of a signal derived from the monitored temperature to control the heat generating device or accessories if so desired.

### FIELD AND BACKGROUND OF INVENTION

This invention relates to apparatus and methods for monitoring temperature. More particularly, the invention employs certain characteristics of diodes in an effective way to monitor the temperature of a heat generating device and enable use of a signal derived from the monitored temperature to control the heat generating device or accessories if so desired.

It has been proposed heretofore to use a thermal diode as a temperature sensor, as shown for example in Bartilson et al U.S. Pat. No. 5,230,564. In such prior proposals, a common goal is the determination of the exact and actual temperature of the monitored device, which may be any of a mechanical device such as a diesel engine, an electromechanical device such as a spark ignition internal combustion engine, or an electrical device such as a motor or a semiconductor chip device. Where that is the accepted goal, significant effort must be put into calibration of any diode used as a sensor, with resultant difficulties in dealing with variations in individual diodes (even among a common manufacturing batch) and operating environments.

Understandably, it is desirable to avoid such calibration problems in a manufacturing situation where large numbers of devices are to be assembled and put out into commerce.

### SUMMARY OF THE INVENTION

With the foregoing in mind, it is one purpose of this invention to achieve acceptable performance by monitoring relative temperature variation rather than exact temperatures. In realizing this purpose, normal manufacturing variation in tolerances are readily accommodated, while the benefits of diode sensors are maintained.

Another purpose of this invention is to provide an equipment manufacturer who must provide temperature monitoring to assure sufficient equipment performance with reasonable and convenient methods of providing such monitoring and, where necessary or appropriate, control over a heat generating device.

### BRIEF DESCRIPTION OF DRAWINGS

Some of the purposes of the invention having been stated, others will appear as the description proceeds, when taken in connection with the accompanying drawings, in which:

FIG. 1 is a schematic representation of a temperature monitoring and control apparatus in accordance with this invention.

FIG. 2 is an illustration of typical temperature/voltage relationships for a diode such as is used in the apparatus of FIG. 1.

FIG. 3 is a flow chart illustrating the steps of a method in accordance with this invention.

### DETAILED DESCRIPTION OF INVENTION

While the present invention will be described more fully hereinafter with reference to the accompanying drawings, in which a preferred embodiment of the present invention is shown, it is to be understood at the outset of the description which follows that persons of skill in the appropriate arts may modify the invention here described while still achieving the favorable results of the invention. Accordingly, the description which follows is to be understood as being a broad, teaching disclosure directed to persons of skill in the appropriate arts, and not as limiting upon the present invention.

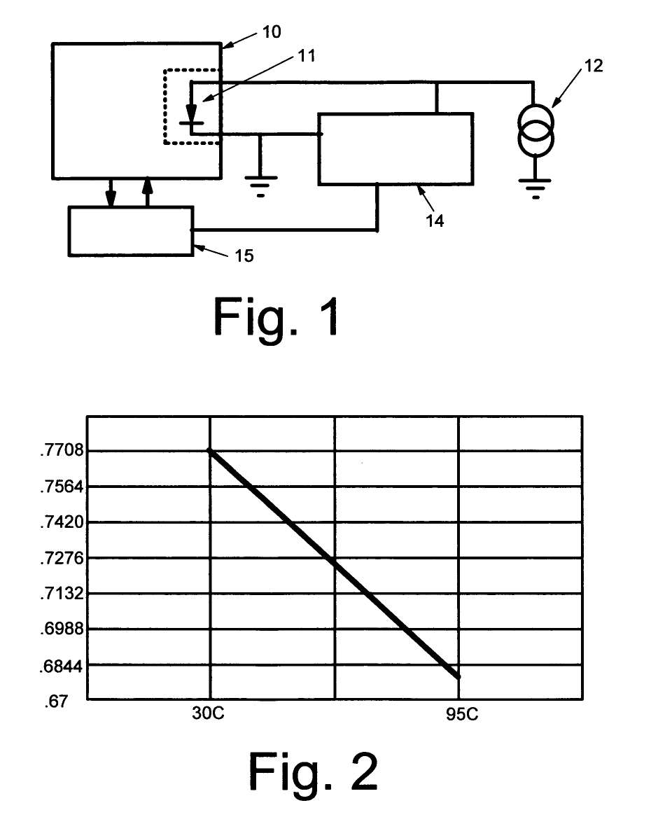

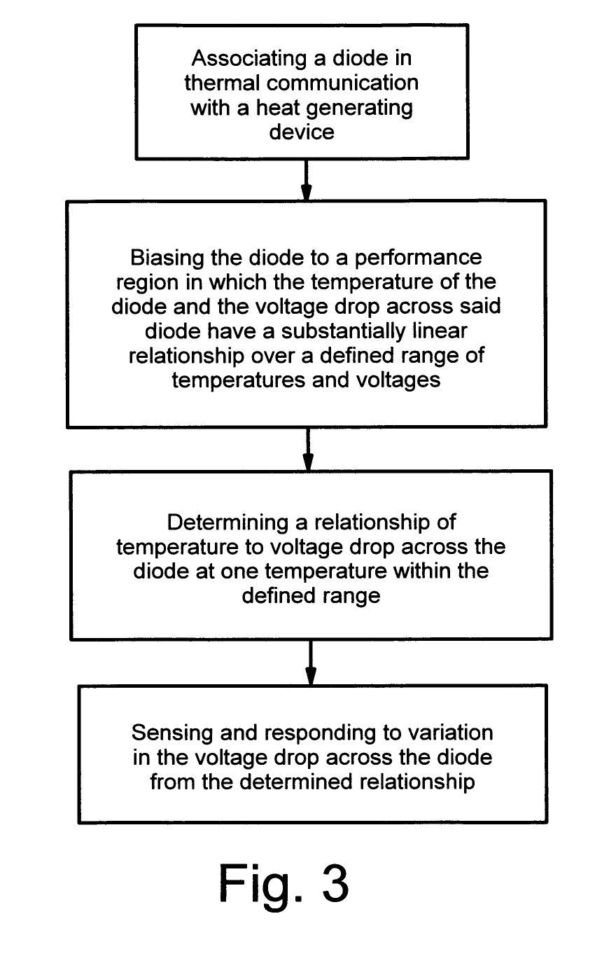

Referring now to FIG. 1, a typical implementation of a temperature monitoring and/or control apparatus is there shown. The block 10 identifies a device which generates heat and the temperature of which is to be monitored and sometimes controlled. The device 10 may be an electrical device such as a motor, an electronic device such as a semiconductor chip or package, a mechanical device such as a diesel engine, or an electromechanical device such as a spark ignition internal combustion engine.

A diode 11 is disposed in thermal communication with the device 10. That is, the diode 11 is subjected to the temperature of the device 10. This may be accomplished in a number of ways. If the device 10 is a mechanical, electromechanical or electrical device of any one of many types, the simplest and most convenient manner of obtaining thermal communication is to bond the diode to the device mechanically or with an appropriate adhesive. In either instance, use of a layer of material which is a good thermal conductor, such as certain types of grease, facilitates assuring that the temperature of the diode 11 is the same as the temperature of the monitored device 10. Such a material may be characterized as having low thermal resistance. Where the device is an integrated circuit device or other electronic subassembly, then it may be possible to simply include the sensor diode among elements formed on a silicon or other substrate.

A voltage supply 12 is electrically connected with the diode 11 and applies to the diode a voltage biasing the diode to a performance region in which the temperature of the diode and the voltage drop across the diode have a substantially linear relationship over a defined range of temperatures and voltages. FIG. 2 shows such a relationship. As there shown, the diode voltage (vertical axis) and temperature (horizontal axis) scales are both linear, as the diode is biased into a region where the dynamic resistance component no longer dominates. This may be done with a constant current voltage supply, preferable for greater assurance of accuracy, or with a simple voltage applied from an available source through a series resistor. When a diode is biased into this region, the diode's ohmic resistance monitored as a voltage drop remains relatively constant over wide current variations. In particular, FIG. 2 represents the distribution of characteristics for a diode embedded within a heat generating device which is a high power integrated circuit device or semiconductor package. That environment is one in which the present invention finds particular usefulness.

Heretofore, apparatus bearing some resemblance to that here described have been used where a requirement is an actual, accurate temperature measurement is desired. In such apparatus and methods, as distinct form this invention, careful attention must be given to, and management must be exercised over, the calibration data from a diode manufacturer, the accuracy and temperature stability of the voltage supply, and the accuracy and temperature stability of associated circuits including a monitoring and control circuit as will be here described.

The present invention contemplates that temperature alarms, regulators and power control systems lack any requirement for actual, accurate absolute temperature measurement. Instead, what is needed is a relative indication or measurement which will enable such results as a high temperature alarm or power modulation. The only thing which is necessary is a determination of the slope of the characteristic curve such as FIG. 2.

The apparatus according to this invention also includes a monitoring and control circuit 14 electrically connected with the diode 11 and the voltage supply 12. The monitoring and control circuit 14 determines a relationship of temperature to voltage drop across the diode at one temperature within the defined range. The circuit senses and responds to a variation from that relationship which is indicative of the temperature of the heat generating device 10.

The apparatus includes an element 15 electrically connected with said monitoring and control circuit and associated with said heat generating device to modulate the heat to which the device 10 is subjected in response to indications of the temperature of the heat generating device sensed by the monitoring and control circuit 14. This element may take the form of a heat extracting device such as a fan, liquid coolant circuit or the like where the concern is that of lowering a temperature. Alternatively, in some circumstance such as use of a device in extreme cold, this element may take the form of a heat supplying device such as a liquid warming circuit where the concern is that of maintaining an operating temperature. Alternatively, the element 15 may be linked to the heat generating device 10 so as to control an operating parameter of the device. Thus, where the device is a semiconductor chip such as a system central processor unit, the element 15 may control the clock speed at which the processor functions, and thereby exert an indirect control over the heat generated and to be dissipated or supplemented. These types of operative associations are indicated by the double arrows pointing between the elements 10 and 15.

The monitoring and control circuit may use a processor to control the steps of a method in accordance with this invention. Where that is the choice, and since the invention relies upon relative measurements and no calibration data is required, a voltage drop at one defined temperature must be established to which future measurements will be compared. Such a value can be derived and fixed at any convenient opportunity during system integration or defined autonomously during normal system operation. Typical values which may need to be defined can be grouped into the following general categories:

Reference levels: a diode voltage drop measured at a defined temperature and recorded in the monitoring and control circuit;

Thresholds: trigger points that signal an action such as a report, alert or adjustment is required;

Limits or boundaries: trigger points that signal fault conditions;

Ranges: temperatures span or spans established as design objectives;

Resolutions: sensitivity of measurement to changes in temperature; and

Slew Rates: sensitivity to rates of change. Multiple reference levels, thresholds and limits or boundaries may be defined either individually or in combination.

Where the monitoring and control circuit is processor based, rules may be defined and coded into the circuit which collectively embody the processes and values described above. Where such rules are implemented, the monitoring and control circuit will initialize when activated, measure a diode voltage drop, and thereafter effectuate future actions based on a relative comparison of current voltage drop with the initial measurement, based on the voltage/temperature slope parameter described above. Actions taken may be, for examples only, turning on or off a fan; turning on or off a pump circulating a liquid cooler or warmer than the device whose temperature is being sensed; sounding an alarm if the temperature of the sensed device is above or below selected operating ranges; throttling back or speeding up the device; logging relative temperatures and actions taken. Inputs for such calculations are the diode voltage/temperature slope; the diode reference voltage and temperature; and the rule definitions.

In the drawings and specifications there has been set forth a preferred embodiment of the invention and, although specific terms are used, the description thus given uses terminology in a generic and descriptive sense only and not for purposes of limitation.

What is claimed is:

1. Apparatus comprising:
a heat generating device;
a diode in thermal communication with said heat generating device;
a voltage supply electrically connected with said diode and applying to said diode a voltage biasing said diode to a performance region in which the temperature of said diode and the voltage drop across said diode have a substantially linear relationship over a defined range of temperatures and voltages;
a monitoring and control circuit electrically connected with said diode and said voltage supply, said monitoring and control circuit determining a relationship of temperature to voltage drop across the diode at one temperature within the defined range and sensing and responding to a variation from that relationship which is indicative of the temperature of said heat generating device; and
an element electrically connected with said monitoring and control circuit and associated with said heat generating device to modulate the dissipation of heat generated by said device in response to indications of the temperature of said heat generating device sensed by said monitoring and control circuit.

2. Apparatus according to claim 1 wherein said heat generating device is an electrical device.

3. Apparatus according to claim 2 wherein said heat generating device is a semiconductor device.

4. Apparatus according to claim 1 wherein said heat generating device is a mechanical device.

5. Apparatus according to claim 1 wherein said heat generating device is an electromechanical device.

6. Apparatus according to claim 1 wherein said diode is embedded in said heat generating device.

7. Apparatus according to claim 1 wherein said diode is in surface contact with said heat generating device.

8. Apparatus according to claim 1 wherein said heat generating device is controllable and further wherein said element is operatively associated with said heat generating device to vary the operation thereof in response to a sensed voltage drop indicative of device temperature.

9. Apparatus according to claim 1 wherein said heat generating device is controllable and further wherein said element is operatively associated with said heat generating device to vary the operation thereof in response to a sensed voltage drop indicative of device temperature deviating from a predetermined set point temperature.

10. Apparatus according to claim 1 wherein said element comprises an active heat exchange device coupled to said heat generating device which controllably transfers heat therewith.

11. Apparatus according to claim 1 wherein said heat generating device is controllable and further wherein said element comprises a device coupled to said heat generating device to controllably vary the activity thereof and the generation of heat thereby.

12. Method comprising:
associating a diode in thermal communication with a heat generating device;
imposing on the diode an electrical voltage which biases the diode to a performance region in which the temperature of said diode and the voltage drop across said diode have a substantially linear relationship over a defined range of temperatures and voltages;
determining a relationship of temperature to voltage drop across the diode at one temperature within the defined range; and
sensing and responding to variation in the voltage drop across the diode from the determined relationship.

13. Method according to claim 12 wherein the diode is associated with an electrical device.

14. Method according to claim 12 wherein the diode is associated with a semiconductor device.

15. Method according to claim 12 wherein the diode is associated with a mechanical device.

16. Method according to claim 12 wherein the diode is associated with an electromechanical device.

17. Method according to claim 12 wherein the diode is embedded in the heat generating device.

18. Method according to claim 12 wherein the diode is in surface contact with the heat generating device.

19. Method according to claim 12 further comprising associating the monitoring and control circuit with the heat generating device and varying the operation of the heat generating device in response to a sensed voltage drop indicative of device temperature.

20. Method according to claim 12 further comprising associating the monitoring and control circuit with the heat generating device and varying the operation thereof in response to a sensed voltage drop indicative of device temperature varying from a predetermined set point temperature.
